(19) United States
(12) Patent Application Publication
(10) Pub. No.: US 2026/0190583 A1
(43) Pub. Date: Jul. 2, 2026

(54) STRETCHABLE DISPLAY DEVICE

(71) Applicant: LG Display Co., Ltd., Seoul (KR)

(72) Inventors: Sung-Joon MIN, Paju-si (KR); Yeon-Jun OH, Paju-si (KR); Do-Joong KIM, Paju-si (KR); Jun-Hyuk SONG, Paju-si (KR); Tae-Hyun KIM, Paju-si (KR)

(73) Assignee: LG Display Co., Ltd., Seoul (KR)

(21) Appl. No.: 19/400,048

(22) Filed: Nov. 25, 2025

(30) Foreign Application Priority Data
Dec. 27, 2024 (KR) 10-2024-0198584

(51) Int. Cl. H10H 29/85

(52) U.S. Cl. CPC H10H 29/8506

(57) ABSTRACT

A stretchable display device includes a display panel capable of being stretched in a first direction and a second direction; a frame coupled with an edge of the display panel; and a plurality of control units inside the frame, wherein a first control unit among the plurality of control units includes a body portion and a spheroidal joint, and the spheroidal joint includes a first joint portion and a second joint portion, and wherein one ends of the first joint portion and the second joint portion are coupled with the body portion, and other ends of the first joint portion and the second joint portion are coupled with respective spheroidal joints of other control units.

### CROSS-REFERENCE TO RELATED APPLICATION

The present application claims priority to Korean Patent Application No. 10-2024-0198584, filed in the Republic of Korea on Dec. 27, 2024, the entire contents of which are hereby expressly incorporated by reference into the present application.

### BACKGROUND

### Technical Field

The present disclosure relates to a display device, and more particularly, to a stretchable display device.

### Description of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that may only be transformed in a specific area or direction, the stretchable display device is able to implement the ultimate free-form and is considered as the most suitable display for the era of the Internet of Things (IoT), 5G, and autonomous vehicles.

The stretchable display device can include a rigid portion in which a pixel is disposed and a soft portion in which a connection line connecting the pixels is disposed. The rigid portion may not be stretched, and the soft portion can be stretched.

However, the stretchable display device can be damaged if excessively stretched.

### SUMMARY

Accordingly, embodiments of the present disclosure are directed to a stretchable display device that substantially obviates one or more of the problems due to limitations and disadvantages of the related art.

An aspect of the present disclosure is to provide a stretchable display device capable of preventing or suppressing potential damages due to excessive stretching.

Additional features and aspects will be set forth in the description that follows, and in part will be apparent from the description, or can be learned by practice of the present disclosure provided herein. Other features and aspects of the present disclosure can be realized and attained by the structure particularly pointed out in the written description, or derivable therefrom, and the claims hereof as well as the appended drawings.

To achieve these and other aspects of the present disclosure, as embodied and broadly described herein, a stretchable display device includes a display panel capable of being stretched in a first direction and a second direction; a frame coupled with an edge of the display panel; and a plurality of control units inside the frame, wherein a first control unit among the plurality of control units includes a body portion and a spheroidal joint, and the spheroidal joint includes a first joint portion and a second joint portion, and wherein one ends of the first joint portion and the second joint portion are coupled with the body portion, and other ends of the first joint portion and the second joint portion are coupled with respective spheroidal joints of other control units.

It is to be understood that both the foregoing general description and the following detailed description are by way of example and explanatory and are intended to provide further explanation of the present disclosure as claimed.

### BRIEF DESCRIPTION OF THE DRAWINGS

The accompanying drawings, which are included to provide a further understanding of the present disclosure and which are incorporated in and constitute a part of this application, illustrate example embodiments of the present disclosure and together with the description serve to explain various principles of the disclosure. In the drawings:

FIG. 1 is a schematic plan view of a stretchable display device according to example embodiments of the present disclosure;

FIG. 2 is a schematic plan view of a stretchable display device stretched in a first direction according to example embodiments of the present disclosure;

FIG. 3 is a schematic plan view of a stretchable display device stretched in a second direction according to example embodiments of the present disclosure;

FIG. 4 is a schematic plan view of a display panel of a stretchable display device according to the example embodiments of the present disclosure;

FIG. 5 is a schematic cross-sectional view corresponding to line I-I′ in FIG. 4;

FIG. 6 is a schematic perspective view of a control unit according to example embodiments of the present disclosure;

FIG. 7 is a schematic exploded perspective view of the control unit according to example embodiments of the present disclosure;

FIG. 8 is a schematic cross-sectional view of the control unit according to example embodiments of the present disclosure;

FIG. 9 is a schematic view showing operation of a control unit according to example embodiments of the present disclosure;

FIG. 10 is a schematic view showing an extended state of the control unit according to example embodiments of the present disclosure;

FIG. 11 is a schematic view showing a rotation range of the control unit according to example embodiments of the present disclosure;

FIG. 12 is a schematic cross-sectional view of a control unit of a first modified example according to example embodiments of the present disclosure;

FIG. 13 is a schematic view showing a rotation range of the control unit of the first modified example according to example embodiments of the present disclosure;

FIG. 14 is a schematic cross-sectional view of a control unit of a second modified example according to example embodiments of the present disclosure;

FIG. 15 is a schematic cross-sectional view of a control unit of a third modified example according to example embodiments of the present disclosure;

FIG. 16 is a schematic cross-sectional view of a control unit of a fourth modified example according to example embodiments of the present disclosure;

FIG. 17 is a schematic cross-sectional view of a control unit of a fifth modified example according to example embodiments of the present disclosure;

FIG. 18 is a schematic view showing a rotation range of the control unit of the fifth modified example according to example embodiments of the present disclosure;

FIG. 19 is a schematic plan view of a stretchable display device according to another example embodiment of the present disclosure;

FIG. 20 is a schematic plan view of a stretchable display device according to yet another example embodiment of the present disclosure;

FIG. 21 is a schematic plan view of a stretchable display device according to still another example embodiment of the present disclosure; and

FIG. 22 is a schematic view of a control unit of a stretchable display device according to yet another example embodiment of the present disclosure.

### DETAILED DESCRIPTION

Advantages and features of the present disclosure and methods for achieving them will be made clear from example embodiments described in detail below with reference to the accompanying drawings. The present disclosure can, however, be implemented in many different forms and should not be construed as being limited to the example embodiments set forth herein. The example embodiments are provided such that this disclosure will be more thorough and complete and will more fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the example embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, where a detailed description of a known related art may unnecessarily obscure aspects or features of the present disclosure, the detailed description thereof may be omitted herein or be briefly discussed.

Where such terms as “including,” “having,” “comprising,” and the like are used in this disclosure, other parts can be added unless a more specific term like “only” is used.

Further, where a component is expressed as being singular, being plural is included, and vice versa, unless otherwise specified.

In analyzing a component, an error range is to be interpreted as being included even where there is no explicit description.

In a description of a positional relationship, for example, where a positional relationship of two parts/layers is described as being “over,” “on,” “above,” “below,” “under,” “next to,” or the like, one or more other parts/layers can be provided between the two parts/layers, unless a more specific term like “immediately” or “directly” is used therewith.

In a description of a temporal relationship, for example, where a temporal predecessor relationship is described as being “after,” “subsequent,” “next to,” “prior to,” or the like, unless a more specific term like “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms first, second, and the like may be used to describe various components, these components are not substantially limited by these terms. These terms are used only to refer to one component separately from another component, and may not define any order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in an associated relationship. Further, the term “can” fully encompasses all the meanings and coverages of the term “may” and vice versa.

A stretchable display device according to example embodiments of the present disclosure can be deformed in various ways such as flexing, stretching, twisting, and squeezing.

Hereinafter, example embodiments of the present disclosure will be described in detail with reference to accompanying drawings. All the components of each display device according to all example embodiments of the present disclosure are operatively coupled and configured.

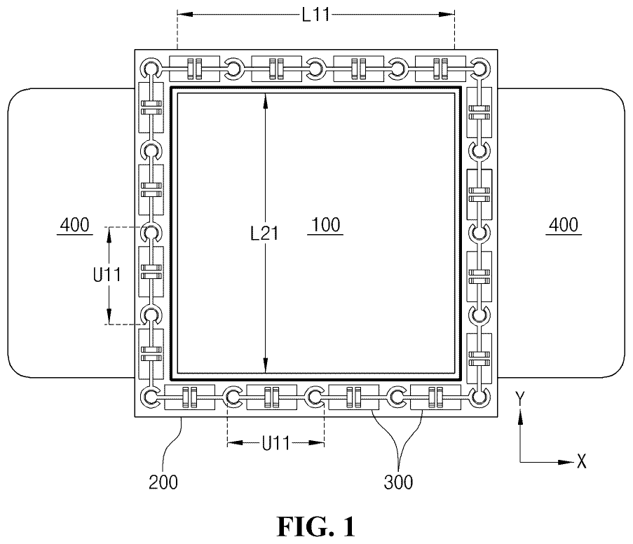

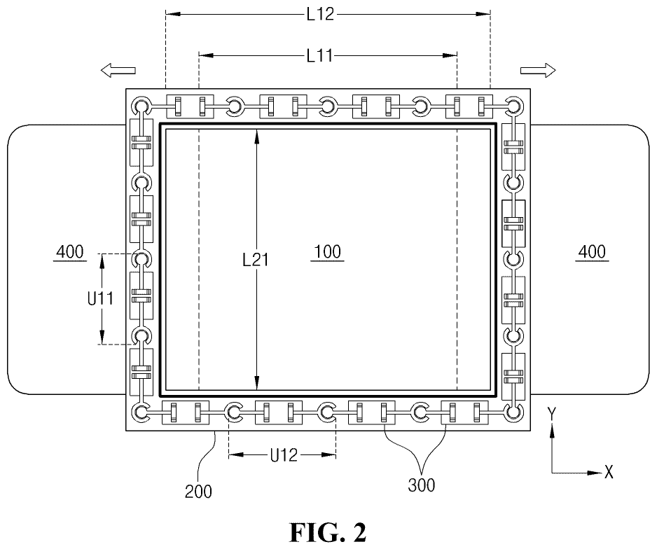

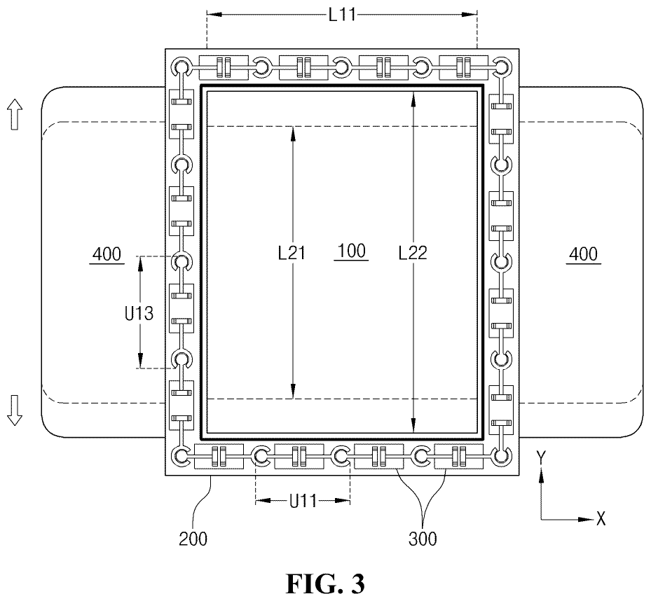

FIG. 1 is a schematic plan view of a stretchable display device according to example embodiments of the present disclosure and shows the stretchable display device in a non-stretched state. FIG. 2 and FIG. 3 are schematic plan views of a stretchable display device in a stretched state according to example embodiments of the present disclosure. FIG. 2 shows the stretchable display device stretched in a first direction, and FIG. 3 shows the stretchable display device stretched in a second direction.

In FIGS. 1 to 3, the stretchable display device according to example embodiments of the present disclosure can include a display panel 100, a frame 200, a plurality of control units 300, and side portions 400 and can be stretched in a first direction X and/or a second direction Y.

The display panel 100 can include a plurality of pixels and display an image. The display panel 100 can be stretched in the first direction X and/or the second direction Y. The non-stretched display panel 100 can have a first horizontal length L11 and a first vertical length L21.

The display panel 100 can have a rectangular shape. However, embodiments of the present disclosure are not limited thereto. In other embodiments, the display panel 100 can have various shapes such as a polygonal shape except for a rectangular shape, a circular shape, or an oval shape.

The frame 200 can surround the display panel 100 and be coupled with an edge of the display panel 100. The frame 200 can be stretched in the first direction X and/or the second direction Y. The frame 200 can be formed of a soft matter or soft material. For example, the frame 200 can be formed of polydimethylsiloxane (PDMS), but is not limited thereto.

The plurality of control units 300 can be provided inside the frame 200. Each control unit 300 can be extended and contracted in a specific direction. The control units 300 can be attached to a cover film of the display panel 100 and attached to the frame 200.

At least two types of control units 300 can be disposed inside the frame 200. For example, the control unit 300 corresponding to a corner of the display panel 100 can have a different shape from the control unit 300 corresponding to other parts.

The control units 300 can be connected to each other and can implement various deformations of the display device using a spheroidal joint and control a stretching speed and limit of the display device using a tube damper. This will be described in detail later.

When the display panel 100 is not stretched, the control unit 300 can be in a state of maximum contraction and can have a first unit length U11. On the other hand, when the display panel 100 is stretched, the control unit 300 can be extended in the stretching direction, and the length of the control unit 300 can be increased. In this case, the increasing length of the control unit 300 can be limited, and thus the stretching range of the display panel 100 can be limited.

Next, the side portions 400 can be provided on both sides of the frame 200 provided with the display panel 100 and the control units 300 in the first direction X, respectively. The side portions 400 can be a part that can hold the display device by hand. An operation unit including various operation buttons related to controlling the display panel 100 can be provided in the side portions 400. In addition, a driving unit for applying signals to the display panel 100 can be provided in the side portions 400.

As shown in FIG. 2, the stretchable display device according to example embodiments of the present disclosure can be stretched in the first direction X. According to this, the stretched display panel 100 can have a second horizontal length L12. The second horizontal length L12 can be greater than the first horizontal length L11 of the non-stretched display panel 100.

In this case, a horizontal length of the frame 200 can also be longer, and the length of the control unit 300 arranged in the first direction X inside the frame 200 can also be longer. Here, the control unit 300 arranged in the first direction X can have a second unit length U12, and the second unit length U12 can be greater than the first unit length U11.

On the other hand, the side portions 400 may not be stretched in the first direction X.

Meanwhile, as shown in FIG. 3, the stretchable display device according to example embodiments of the present disclosure can be stretched in the second direction Y. According to this, the stretched display panel 100 can have a second vertical length L22. The second vertical length L22 can be greater than the first vertical length L21 of the non-stretched display panel 100.

In this case, a vertical length of the frame 200 can also be longer, and the length of the control unit 300 arranged in the second direction Y inside the frame 200 can also be longer. Here, the control unit 300 arranged in the second direction Y can have a third unit length U13, and the third unit length U13 can be greater than the first unit length U11.

In addition, the side portions 400 can also be stretched in the second direction Y. The side portions 400 can be formed of stretchable plastic. However, embodiments of the present disclosure are not limited thereto. In other embodiments, the side portions 400 can include a plurality of separate parts that can be moved independently in a stretching direction, that is, the second direction Y.

As such, in the stretchable display device according to example embodiments of the present disclosure, by providing the plurality of control units 300 inside the frame 200 surrounding the display panel 100 and limiting the stretching range of the display panel 100, the display panel 100 can be prevented or protected from being damaged due to excessive stretching.

The stretchable display device according to example embodiments of the present disclosure can be applied to devices such as game consoles but is not limited thereto.

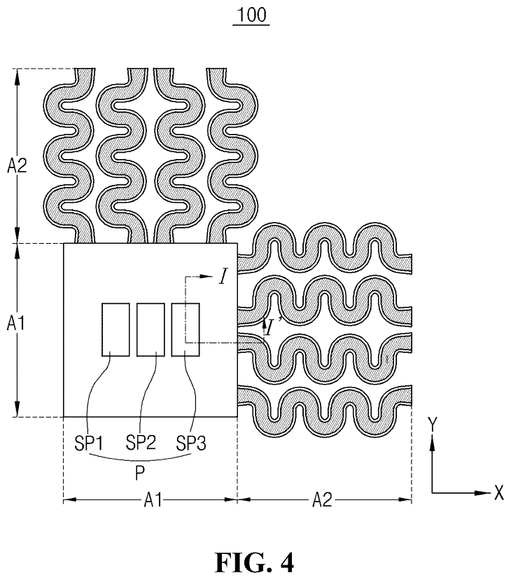

A planar configuration of the display panel 100 of the stretchable display device according to example embodiments of the present disclosure will be described in detail with reference to FIG. 4.

FIG. 4 is a schematic plan view of a display panel of a stretchable display device according to example embodiments of the present disclosure.

As shown in FIG. 4, the display panel 100 of the stretchable display device according to example embodiments of the present disclosure can be stretched in the first direction X and/or the second direction Y. The display panel 100 can include a rigid portion A1 as a first area and a soft portion A2 as a second area. The rigid portion A1 may not be stretched, and the soft portion A2 can be stretched.

The rigid portion A1 can be provided in the form of an island, and a plurality of rigid portions A1 can be disposed to be spaced apart from each other along the first direction X and the second direction Y. The rigid portions A1 can be disposed in a matrix form. For example, the rigid portion A1 can have a substantially rectangular shape.

A pixel P including a plurality of sub-pixels SP1, SP2, and SP3 can be provided in each rigid portion A1. For example, first, second, and third sub-pixels SP1, SP2, and SP3 can be provided in each rigid portion A1, and the first, second, and third sub-pixels SP1, SP2, and SP3 can be red, green, and blue sub-pixels, respectively.

The first, second, and third sub-pixels SP1, SP2, and SP3 can be sequentially arranged in the first direction X and can have a rectangular shape. Each of the first, second, and third sub-pixels SP1, SP2, and SP3 can include a light-emitting element, at least one thin film transistor, and at least one capacitor.

The soft portion A2 can be disposed between adjacent rigid portions A1 in the first direction X and between adjacent rigid portions A1 in the second direction Y. A stretchable line that is a connection line connecting adjacent pixels P can be provided in the soft portion A2. The stretchable line can include a plurality of voltage lines such as a gate line, a data line, a high potential line, a low potential line, an emission signal line, a reference voltage line, and so on.

The stretchable line can have at least one curved part. For example, the stretchable line can have a wave structure of alternating vertices in opposite directions or repeating peaks and valleys and can include a plurality of wave shapes of repeated crests and troughs. Four stretchable lines can be disposed between adjacent rigid portions A1, and two stretchable lines can be disposed symmetrically to other two stretchable lines.

However, embodiments of the present disclosure are not limited thereto. The stretchable line can have various structures. For example, in other embodiments, the stretchable line can have an omega structure including at least one omega shape, among other possibilities. The omega shape can include at least one curved part and at least one straight part, and the straight part can be disposed substantially parallel to an extension direction of the stretchable line.

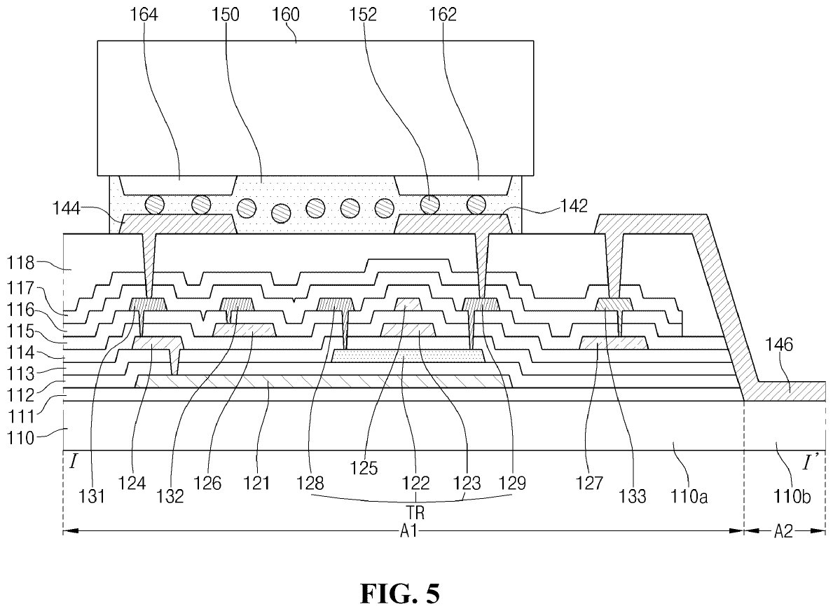

A cross-sectional configuration of the display panel 100 of the stretchable display device will be described with reference to FIG. 5.

FIG. 5 is a schematic cross-sectional view of a display panel of a stretchable display device according to example embodiments of the present disclosure and shows a cross-section corresponding to line I-I′ in FIG. 4.

As shown in FIG. 5, the display panel 100 of the stretchable display device according to example embodiments of the present disclosure can include a base substrate 110 on which the rigid portion A1 and the soft portion A2 are disposed. The base substrate 110 can include a first base portion 110a corresponding to the rigid portion A1 and a second base portion 110b corresponding to the soft portion A2.

The first base portion 110a can be provided in a plate shape in a display area and can serve to support and protect components of a plurality of sub-pixels SP1, SP2, and SP3. The second base portion 110b can be provided between the first base portions 110a adjacent to each other in each of the first direction X and the second direction Y. The second base portion 110b can include at least one curved part and can serve to support and protect a stretchable line 146. The first and second base portions 110a and 110b can be connected to each other and provided as one-body.

Although not shown in the figure, a first flexible substrate formed of a soft matter or soft material can be provided under the base substrate 110. The first flexible substrate can be attached to a bottom surface of the base substrate 110 by a first adhesive layer.

The base substrate 110 can be formed of a rigid material having lower flexibility than the soft material of the first flexible substrate. For example, the base substrate 110 can be formed of a polyimide (PI) resin or epoxy resin, among others.

On the other hand, the first flexible substrate can be formed of a soft matter or soft material with bending or stretching properties. For example, the first flexible substrate can be formed of silicone rubber such as polydimethylsiloxane (PDMS), elastomer such as polyurethane (PU), or styrene butadiene block copolymer such as styrene butadiene styrene (SBS), among others.

Further, the first adhesive layer can be formed of an acryl-based, silicon-based, or urethane-based adhesive. For example, the first adhesive layer can be optically clear adhesive (OCA) or optically clear resin (OCR).

Next, a first buffer layer 111 can be provided on the base substrate 110. The first buffer layer 111 can be formed as a single layer or multiple layers of an inorganic insulating material. For example, the inorganic insulating material can include silicon nitride (SiNx), silicon oxide (SiOx), or silicon oxynitride (SiON).

To prevent or suppress damage of the first buffer layer 111 such as cracks due to stretching, the first buffer layer 111 can be provided only over the first base portion 110a and may not be provided over the second base portion 110b.

A light-shielding layer 121 can be provided on the first buffer layer 111 of the rigid portion A1. The light-shielding layer 121 can be formed of a conductive material such as metal. For example, the light-shielding layer 121 can be formed of at least one of aluminum (Al), copper (Cu), molybdenum (Mo), titanium (Ti), chromium (Cr), nickel (Ni), tungsten (W), or an alloy thereof. The light-shielding layer 121 can have a single-layered structure or a multiple-layered structure.

A second buffer layer 112 can be provided on the light-shielding layer 121 of the rigid portion A1 and can be formed of an inorganic insulating material. A semiconductor layer 122 can be provided on the second buffer layer 112 of the rigid portion A1.

The semiconductor layer 122 can include a channel region at its central part and source and drain regions at both sides of the channel region. The semiconductor layer 122 can be formed of oxide semiconductor material or polycrystalline silicon.

A gate insulation layer 113 can be provided on the semiconductor layer 122 of the rigid portion A1 and can be formed of an inorganic insulating material. A gate electrode 123 and a first connection electrode 124 can be provided on the gate insulation layer 113 of the rigid portion A1 and can be formed of a conductive material such as metal.

The gate electrode 123 can overlap the semiconductor layer 122 and can be disposed to correspond to the central part of the semiconductor layer 122. The first connection electrode 124 can be in contact with the light-shielding layer 121.

A first interlayer insulation layer 114 can be provided on the gate electrode 123 of the rigid portion A1 and the first connection electrode 124 and can be formed of an inorganic insulating material. An auxiliary electrode 125, an auxiliary line 126, and a pad electrode 127 can be provided on the first interlayer insulation layer 114 of the rigid portion A1 and can be formed of a conductive material such as metal.

A second interlayer insulation layer 115 can be provided on the auxiliary electrode 125, the auxiliary line 126, and the pad electrode 127 of the rigid portion A1 and can be formed of an inorganic insulating material. A source electrode 128, a drain electrode 129, a second connection electrode 131, and a power line 132 can be provided on the second interlayer insulation layer 115 of the rigid portion A1 and can be formed of a conductive material such as metal.

The source electrode 128 and the drain electrode 129 can be spaced apart from each other with the gate electrode 123 positioned therebetween and can be in contact with both ends of the semiconductor layer 122.

The semiconductor layer 122, the gate electrode 123, the source electrode 128, and the drain electrode 129 can constitute a thin film transistor TR.

The second connection electrode 131 can be in contact with the first connection electrode 124 and the power line 132 can be in contact with the auxiliary line 126. For example, the power line 132 can be a signal line supplying a low potential voltage ELVSS.

Next, a third interlayer insulation layer 116 can be provided on the source electrode 128, the drain electrode 129, the second connection electrode 131, and the power line 132 of the rigid portion A1 and can be formed of an inorganic insulating material. An auxiliary pad 133 can be provided on the third interlayer insulation layer 116 of the rigid portion A1 and can be formed of a conductive material such as metal.

A passivation layer 117 can be provided on the auxiliary pad 133 of the rigid portion A1 and can be formed of an inorganic insulating material. A planarization layer 118 can be provided on the passivation layer 117 of the rigid portion A1. The planarization layer 118 can eliminate a step difference due to the layers thereunder and can have a substantially flat top surface. The planarization layer 118 can be formed of an organic insulating material such as photosensitive acrylic polymer (photo acryl).

A first electrode 142, a second electrode 144, and the stretchable line 146 can be provided on the planarization layer 118 of the rigid portion A1 and can be formed of a conductive material such as metal. The first electrode 142 can be in contact with the drain electrode 129 and the second electrode 144 can be in contact with the second connection electrode 131.

One end of the stretchable line 146 can be disposed on the planarization layer 118 of the rigid portion A1 and can be in contact with the auxiliary pad 133. The stretchable line 146 can extend into and be provided in the soft portion A2. The stretchable line 146 can be in contact with the top surface of the second base portion 110b in the soft portion A2.

Meanwhile, although not shown in the figures, a bank layer can be further provided on the first electrode 142, the second electrode 144, and the stretchable line 146 in the rigid portion A1.

Next, an adhesive layer 150 can be provided on the first and second electrodes 142 and 144 of the rigid portion A1. The adhesive layer 150 can be an anisotropic conductive film (ACF) including an insulating base member and a plurality of conductive balls 152 dispersed in the insulating base member.

A light-emitting element 160 can be provided on the adhesive layer 150. The light-emitting element 160 can include a first element electrode 162 and a second element electrode 164. Here, the first element electrode 162 can be a p-electrode, and the second element electrode 164 can be an n-electrode. The first element electrode 162 can be an anode, and the second element electrode 164 can be a cathode. However, embodiments of the present disclosure are not limited thereto.

The light-emitting element 160 can be provided in the form of a micro light-emitting diode chip (micro LED chip or uLED chip) including the n-electrode, an n-type layer, an active layer, a p-type layer, and the p-electrode. The light-emitting element 160 can have a flip-chip structure. Alternatively, the light-emitting element 160 can have a lateral structure or a vertical structure.

The first element electrode 162 of the light-emitting element 160 can be electrically connected to the first electrode 142 through some conductive balls 152 of the adhesive layer 150, and the second element electrode 164 can be electrically connected to the second electrode 144 through other conductive balls 152 of the adhesive layer 150.

Meanwhile, although not shown in the figure, a second flexible substrate can be provided over the light-emitting element 160 and the stretchable line 146 and can be formed of a soft matter or soft material. The second flexible substrate can be formed of the same material as the first flexible substrate.

The second flexible substrate can be attached to the light-emitting element 160 and the stretchable line 146 by a second adhesive layer. The second adhesive layer can be formed of the same material as the first adhesive layer.

In addition, although not shown in the figures, a cover film can be attached onto the second flexible substrate.

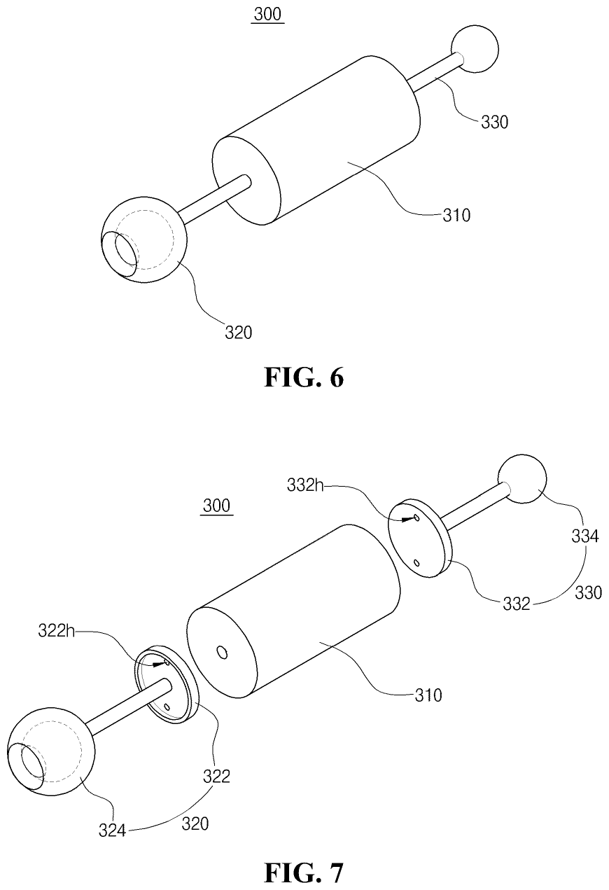

A configuration of the control unit according to example embodiments of the present disclosure will be described in detail with reference to FIGS. 6 to 8.

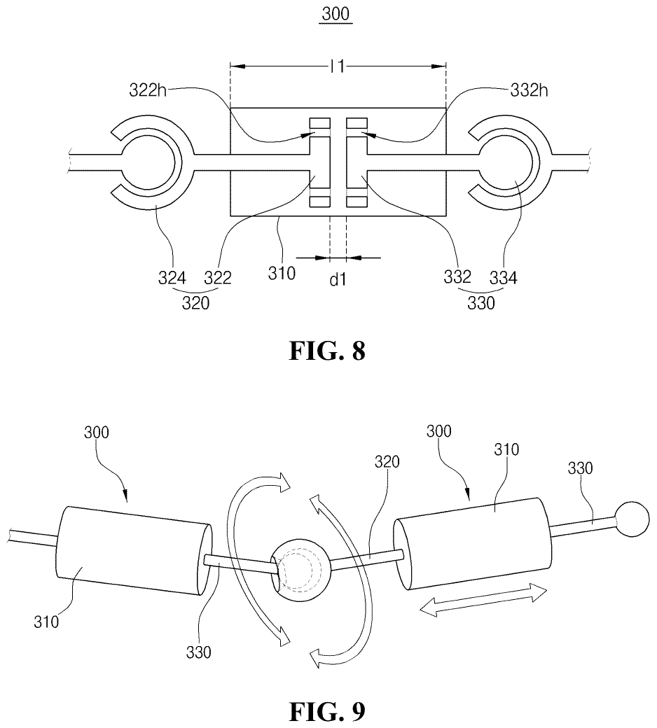

FIG. 6 is a schematic perspective view of a control unit according to example embodiments of the present disclosure, FIG. 7 is a schematic exploded perspective view of the control unit according to example embodiments of the present disclosure, and FIG. 8 is a schematic cross-sectional view of the control unit according to example embodiments of the present disclosure.

As shown in FIGS. 6 to 8, the control unit 300 according to example embodiments of the present disclosure can extend in one direction and can include a body portion 310 and a spheroidal joint 320 and 330 (which, in some embodiments, may be referred to as a first junction portion 320 or a second junction portion 330). The control unit 300 can be a horizontal type for connection in one direction and can be disposed to correspond to a side surface of the display panel 100.

The body portion 310 can be provided with gas or fluid inside and can form a tube damper together with one end of the spheroidal joint 320 and 330 to thereby control a stretching speed and limit of the display device.

The body portion 310 can have a substantially circular column shape. However, embodiments of the present disclosure are not limited thereto. In other embodiments, the body portion 310 can have a rectangular column shape or a polygonal column shape except for the rectangular column shape.

A length l1 of the body portion 310 can correspond to substantially a stretching length. That is, the display device can be stretched by the length l1 of the body portion 310.

The spheroidal joint 320 and 330 can include a first joint portion 320 and a second joint portion 330. The first joint portion 320 and the second joint portion 330 can extend in the one direction. One ends of the first joint portion 320 and the second joint portion 330 can be coupled with the body portion 310, and other ends of the first joint portion 320 and the second joint portion 330 can be coupled with respective spheroidal joints 320 and 330 of other control units 300, thereby implementing various deformations of the display device.

Specifically, the first joint portion 320 and the second joint portion 330 can include first coupling parts 322 and 332 at the one ends and second coupling parts 324 and 334 at the other ends.

The first coupling parts 322 and 332 of the first and second joint portions 320 and 330 can have a substantially disk shape and can be disposed to face each other inside the body portion 310. Edges of the first coupling parts 322 and 332 can protrude toward the second coupling parts 324 and 334.

In a non-stretched state, the first coupling parts 322 and 332 of the first and second joint portions 320 and 330 can be spaced apart from each other with a first distance d1. However, embodiments of the present disclosure are not limited thereto. In other embodiments, the first coupling parts 322 and 332 of the first and second joint portions 320 and 330 can be disposed to be in contact with each other in the non-stretched state.

Each of the first coupling parts 322 and 332 can have at least one control hole 322h and 332h, and the control holes 322h and 332h of the first coupling parts 322 and 332 can be disposed to face each other. For example, two control holes 322h and 332h can be provided in each of the first coupling parts 322 and 332, but is not limited thereto.

The second coupling parts 324 and 334 of the first and second joint portions 320 and 330 can be disposed outside the body portion 310 and can be coupled with respective second coupling parts 324 and 334 of other control units 300. Here, the second coupling part 324 of the first joint portion 320 can be a female joint and can have a mortar shape. The second coupling part 334 of the second joint portion 330 can be a male joint and can have a pestle shape.

Accordingly, the second coupling part 324 of the first joint portion 320 can be coupled with a second coupling part 334 of a second joint portion 330 of another control unit 300, and the second coupling part 334 of the second joint portion 330 can be coupled with a second coupling part 324 of a first joint portion 320 of one other control unit 300.

In this case, an opening of the second coupling part 324 of the first joint portion 320 can be provided on a side of one direction, that is, on a side of a longitudinal direction of the control unit 300. To prevent or suppress separation between the second coupling parts 324 and 334 of the first and second joint portions 320 and 330 of adjacent control units 300 that have been coupled, a size of the opening, i.e., a maximum length of the opening can be smaller than a diameter of the second coupling part 334 of the second joint portion 330.

The operation of the control unit 300 will be described with reference to FIGS. 9 to 11.

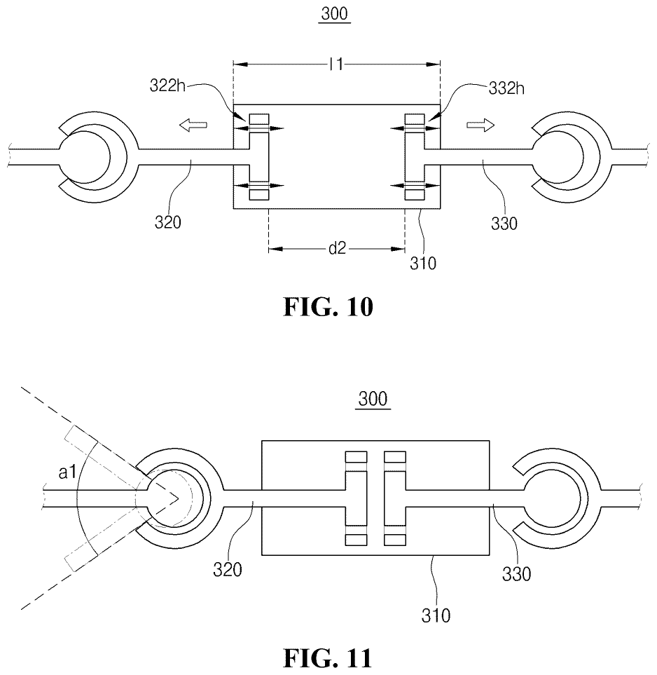

FIG. 9 is a schematic view showing operation of a control unit according to example embodiments of the present disclosure, FIG. 10 is a schematic view showing an extended state of the control unit according to example embodiments of the present disclosure, and FIG. 11 is a schematic view showing a rotation range of the control unit according to example embodiments of the present disclosure.

As shown in FIGS. 9 to 11, one control unit 300 can be extended and contracted in a longitudinal direction and can be united with another control unit 300 and rotated.

As shown in FIG. 10, when the display device is stretched, the first joint portion 320 and the second joint portion 330 of the control unit 300 can move outward, so that the control unit 300 can be extended and the length of the control unit 300 can be increased. In this case, the first coupling parts 322 and 332 of the first and second joint portions 320 and 330 can be spaced apart from each other with a second distance d2.

The second distance d2 can be greater than the first distance d1 and smaller than the length l1 of the body portion 310. That is, the control unit 300 can be extended within a range of the length l1 of the body portion 310.

Here, when the first joint portion 320 and the second joint portion 330 move along a longitudinal direction of the body portion 310, the flow rate of the gas or fluid can be controlled through the control holes 322h and 332h, thereby controlling the operating speed. Accordingly, the operating speed can be controlled by adjusting the number and area of the control holes 322h and 332h.

The operating speed can be proportional to the number and area of the control holes 322h and 332h. That is, as the number or area of the control holes 322h and 332h increases, the operating speed can get faster, and as the number or area of the control holes 322h and 332h decreases, the operating speed can get slower.

Meanwhile, as shown in FIG. 11, the control unit 300 can rotate by a first angle a1 with respect to another control unit 300 united with the control unit 300.

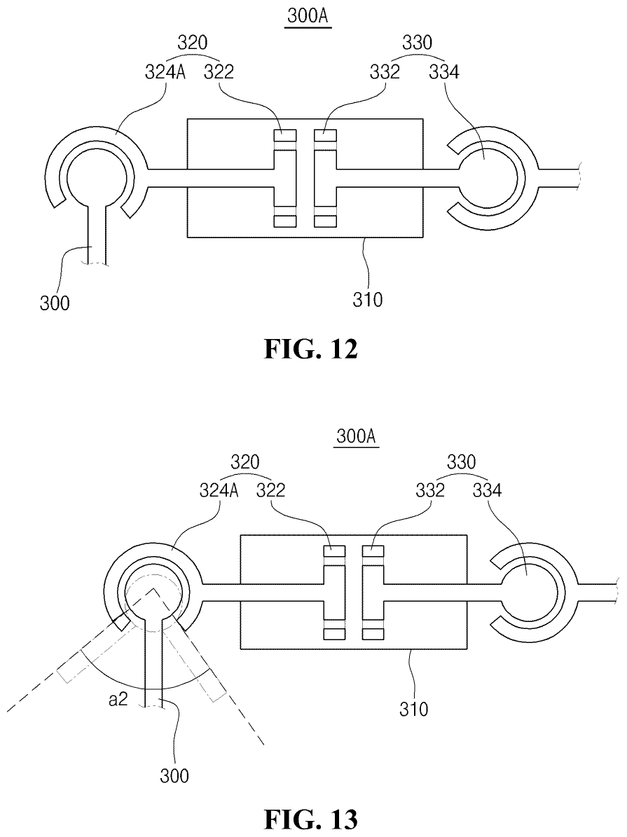

The control unit 300 can be variously modified, which will be described with reference to FIGS. 12 to 18.

FIG. 12 is a schematic cross-sectional view of a control unit of a first modified example according to example embodiments of the present disclosure, and FIG. 13 is a schematic view showing a rotation range of the control unit of the first modified example according to example embodiments of the present disclosure.

As shown in FIG. 12 and FIG. 13, the control unit 300A of the first modified example according to example embodiments of the present disclosure can extend in one direction and can include the body portion 310 and the spheroidal joint 320 and 330. The spheroidal joint 320 and 330 can include the first joint portion 320 and the second joint portion 330. The first joint portion 320 and the second joint portion 330 can include the first coupling parts 322 and 332 at one ends thereof and the second coupling parts 324A and 334 at other ends thereof.

The control unit 300A of the first modified example according to example embodiments of the present disclosure can be a vertical type for connection in a direction perpendicular to one direction. The vertical-type control unit 300A can be disposed to correspond to a corner of the display panel 100 and can be vertically united with the horizontal-type control unit 300.

Here, the opening of the second coupling part 324A of the first joint portion 320 can be provided on a side substantially perpendicular to one direction, that is, on a side substantially perpendicular to the longitudinal direction of the control unit 300A. A size of the opening of the vertical-type control unit 300A, i.e., the maximum length of the opening can be smaller than the diameter of the second coupling part 334 of the second joint portion 330 and can be greater than the size of the opening of the horizontal-type control unit 300 of FIG. 8.

Accordingly, as shown in FIG. 13, the vertical-type control unit 300A and the horizontal-type control unit 300 united with each other can rotate by a second angle a2 with respect to one another, and the second angle a2 can be greater than the first angle a1 of FIG. 11.

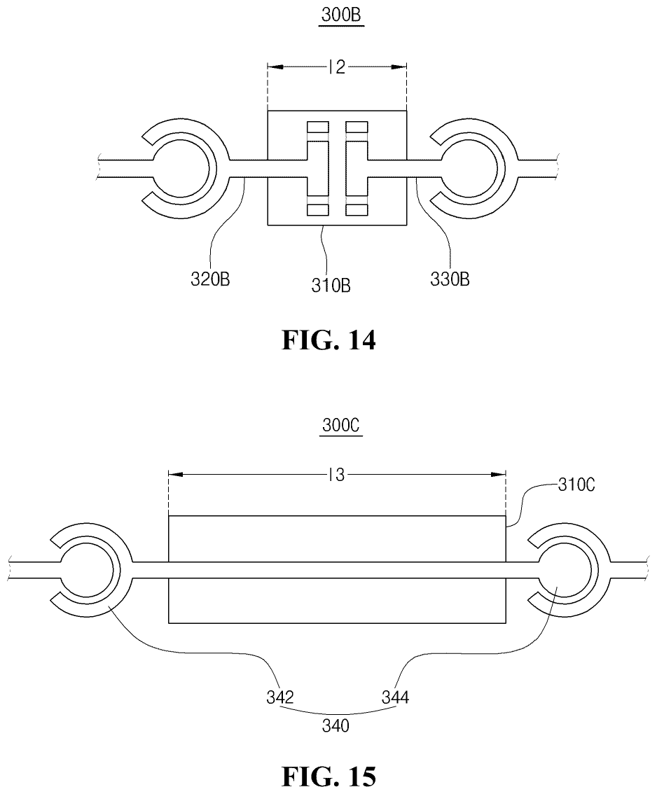

FIG. 14 is a schematic cross-sectional view of a control unit of a second modified example according to example embodiments of the present disclosure.

As shown in FIG. 14, the control unit 300B of the second modified example according to example embodiments of the present disclosure can extend in one direction and can include the body portion 310B and the spheroidal joint 320B and 330B. The spheroidal joint 320B and 330B can include the first joint portion 320B and the second joint portion 330B.

Here, a length l2 of the body portion 310B of the control unit 300B of the second modified example can be smaller than the length l1 of the body portion 310 of the horizontal-type control unit 300 of FIG. 8. In addition, lengths of the first and second joint portions 320B and 330B of the control unit 300B of the second modified example can also be smaller than the lengths of the first and second joint portions 320 and 330 of the horizontal-type control unit 300 of FIG. 8.

The control unit 300B of the second modified example according to example embodiments of the present disclosure can be a short-body type and can be disposed to correspond to an area with a wide range of stretching.

FIG. 15 is a schematic cross-sectional view of a control unit of a third modified example according to example embodiments of the present disclosure.

As shown in FIG. 15, the control unit 300C of the third modified example according to example embodiments of the present disclosure can extend in one direction and can include the body portion 310C and a single joint portion 340. The joint portion 340 can include a first connection part 342 and a second connection part 344. The first connection part 342 and the second connection part 344 can be disposed outside the body portion 310C. The first connection part 342 can be a female joint and can have a mortar shape. The second connection part 344 can be a male joint and can have a pestle shape.

Here, a length l3 of the body portion 310C of the control unit 300C of the third modified example can be greater than the length l1 of the body portion 310 of the horizontal-type control unit 300 of FIG. 8.

In addition, the control unit 300C of the third modified example can include the single joint portion 340, and a length of the joint portion 340 can also be greater than the length of the first and second joint portions 320 and 330 of the horizontal-type control unit 300 of FIG. 8.

The control unit 300C of the third modified example according to example embodiments of the present disclosure can be a long-body type and can be disposed to correspond to an area where stretching is not necessary.

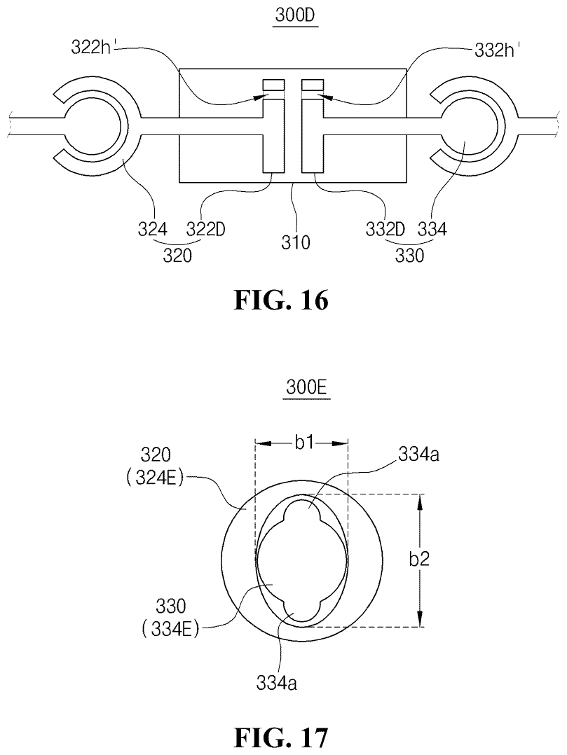

FIG. 16 is a schematic cross-sectional view of a control unit of a fourth modified example according to example embodiments of the present disclosure.

As shown in FIG. 16, the control unit 300D of the fourth modified example according to example embodiments of the present disclosure can extend in one direction and can include the body portion 310 and the spheroidal joint 320 and 330. The spheroidal joint 320 and 330 can include the first joint portion 320 and the second joint portion 330. The first joint portion 320 and the second joint portion 330 can include the first coupling parts 322D and 332D at one ends thereof and the second coupling parts 324 and 334 at other ends thereof.

Each of the first coupling parts 322D and 332D can have one control hole 322h′ and 332h′, and the control holes 322h′ and 332h′ of the first coupling parts 322D and 332D can be disposed to face each other.

The number of the control holes 322h′ and 332h′ of the control unit 300D of the fourth modified example according to example embodiments of the present disclosure can be smaller than the number of the control holes 322h and 332h of the horizontal-type control unit 300 of FIG. 8. Accordingly, when the control unit 300D of the fourth modified example is extended and contracted, a greater load can be applied to the control unit 300D than the horizontal-type control unit 300, so the operating speed can be slow.

The control unit 300D of the fourth modified example according to example embodiments of the present disclosure can be a strong-load type and can be disposed to correspond to an area where a relatively slow operating speed is required. On the other hand, the control unit 300 of FIG. 8 can be a weak-load type and can be disposed to correspond to an area where a relatively fast operating speed is required. Accordingly, the stretching speed can be uniformly controlled.

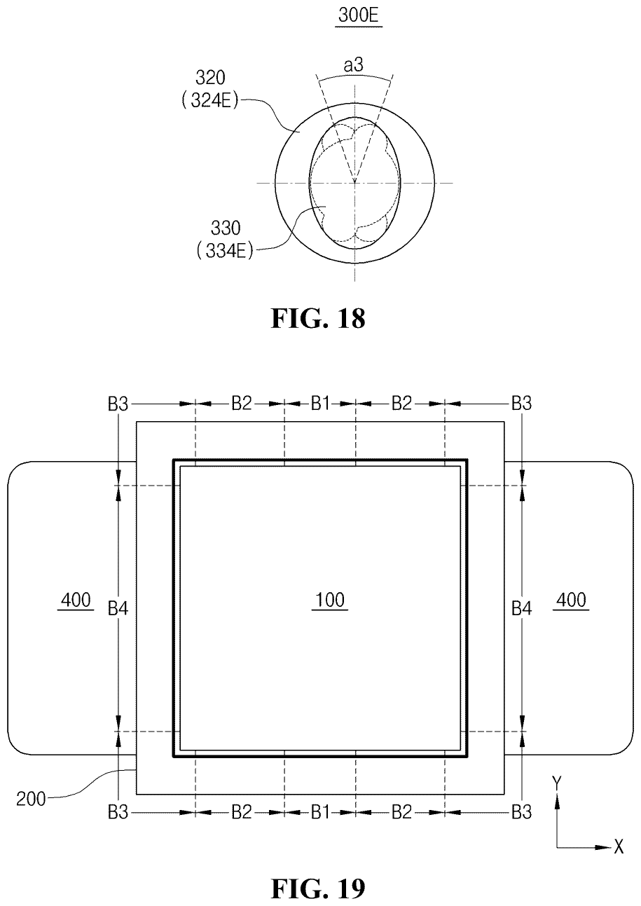

FIG. 17 is a schematic cross-sectional view of a control unit of a fifth modified example according to example embodiments of the present disclosure, and FIG. 18 is a schematic view showing a rotation range of the control unit of the fifth modified example according to example embodiments of the present disclosure.

As shown in FIG. 17 and FIG. 18, in the control unit 300E of the fifth modified example according to example embodiments of the present disclosure, the inside of the second coupling part 324E of the first joint portion 320 can have an oval shape with a long axis and a short axis, and the second coupling part 334E of the second joint portion 330 can have protrusions 334a on both sides in the long axis.

Accordingly, rotation of the second coupling part 334E of the second joint portion 330 can be limited inside the second coupling part 324E of the first joint portion 320. That is, the control unit 300E of the fifth modified example according to example embodiments of the present disclosure can rotate by a third angle a3, and the third angle a3 can be smaller than the first angle a1 of FIG. 11 and the second angle a2 of FIG. 13.

The control unit 300E of the fifth modified example according to example embodiments of the present disclosure can be a rotation-restricted type and can be disposed to correspond to a center of a side of the display panel 100. Accordingly, the radius of rotation can be limited during twist deformation, so that damage due to excessive stretching can be prevented or suppressed.

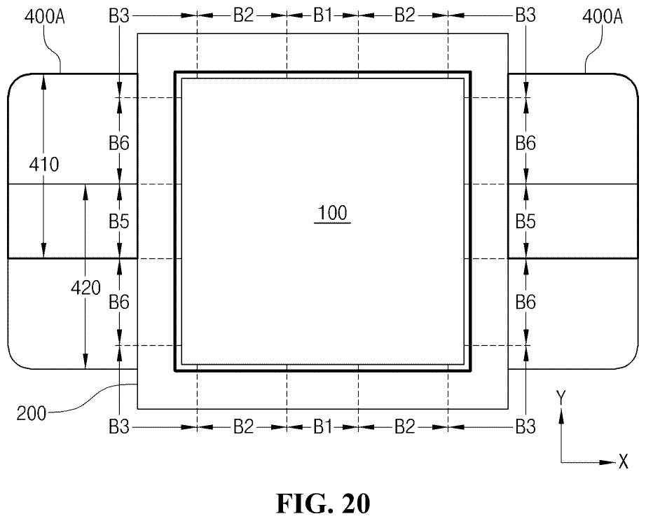

By selectively disposing the various types of control units, the stretchable display devices according to example embodiments of the present disclosure can be deformed without damage due to the excessive stretching, and this will be described with reference to FIG. 19 and FIG. 20.

FIG. 19 is a schematic plan view of a stretchable display device according to another example embodiment of the present disclosure.

As shown in FIG. 19, the display panel 100 of the stretchable display device according to another example embodiment of the present disclosure can include first, second, and third areas B1, B2, and B3 in the first direction X and include third and fourth areas B3 and B4 in the second direction Y.

The third area B3 can correspond to the corner of the display panel 100, and the vertical-type control unit 300A of FIG. 12 can be disposed in the third area B3.

The second areas B2 can be disposed between the third areas B3 in the first direction X, and the first area B1 can be disposed between the second areas B2 in the first direction X. That is, the first area B1 can correspond to the center of the side of the display panel 100, and the rotation-restricted type control unit 300E of FIG. 17 can be disposed in the first area B1.

In addition, the horizontal-type control unit 300 of FIG. 8 and/or the short-body type control unit 300B of FIG. 14 can be selectively disposed in the second area B2.

Meanwhile, the fourth area B4 can be disposed between the third areas B3 in the second direction Y. At least one long-body type control unit 300C of FIG. 15 can be disposed in the fourth area B4.

Accordingly, the stretchable display device according to another example embodiment of the present disclosure can be stretched only in the first direction X and can be fixed without being stretched in the second direction Y.

FIG. 20 is a schematic plan view of a stretchable display device according to yet another example embodiment of the present disclosure.

As shown in FIG. 20, the display panel 100 of the stretchable display device according to one other embodiment of the present disclosure can include first, second, and third areas B1, B2, and B3 in the first direction X and include third, fifth, and sixth areas B3, B5, and B6 in the second direction Y.

In addition, the side portions 400A can include a first side unit 410 and a second side unit 420 overlapping each other in the second direction Y, and the first and second side units 410 and 420 can move independently in the second direction Y.

The third area B3 can correspond to the corner of the display panel 100, and the vertical-type control unit 300A of FIG. 12 can be disposed in the third area B3.

The second areas B2 can be disposed between the third areas B3 in the first direction X, and the first area B1 can be disposed between the second areas B2 in the first direction X. That is, the first area B1 can correspond to the center of the side of the display panel 100, and the rotation-restricted type control unit 300E of FIG. 17 can be disposed in the first area B1.

In addition, the horizontal-type control unit 300 of FIG. 8 and/or the short-body type control unit 300B of FIG. 14 can be selectively disposed in the second area B2.

Meanwhile, the sixth areas B6 can be disposed between the third areas B3 in the second direction Y, and the fifth area B5 can be disposed between the sixth areas B6 in the second direction Y. The fifth area B5 can correspond to an overlapping area of the first and second side units 410 and 420.

The weak-load type control unit 300 of FIG. 8 can be disposed in the fifth area B5, and the strong-load type control unit 300D of FIG. 16 can be disposed in the sixth area B6. Thus, the stretching speed can be uniformly controlled in the second direction Y.

Accordingly, the stretchable display device according to yet another example embodiment of the present disclosure can be stretched in the first direction X and the second direction Y.

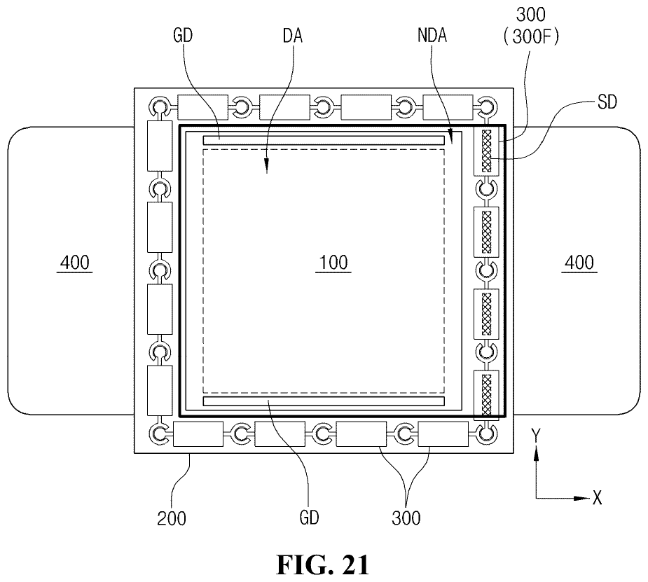

Meanwhile, the driving unit for applying signals to the display panel 100 can be provided to correspond to the control unit. Such a stretchable display device according to still another example embodiment of the present disclosure will be described with reference to FIG. 21.

FIG. 21 is a schematic plan view of a stretchable display device according to still another example embodiment of the present disclosure.

As shown in FIG. 21, the display panel 100 can include a display area DA implementing an image and a non-display area NDA surrounding the display area DA, and the non-display area NDA can overlap the frame 200.

A gate driving unit GD can be provided on the display panel 100. The gate driving unit GD can be disposed in portions of the non-display area NDA extending in the first direction X and facing each other in the second direction Y.

One side of the display panel 100 can extend into the inside of the frame 200 and overlap the control unit 300F. The control unit 300F can be disposed in the non-display area NDA of the display panel 100.

In addition, a source driving unit SD can be provided in the non-display area NDA of the display panel 100 inside the frame 200. The source driving unit SD can overlap the control unit 300F, and the control unit 300F can have a recessed portion.

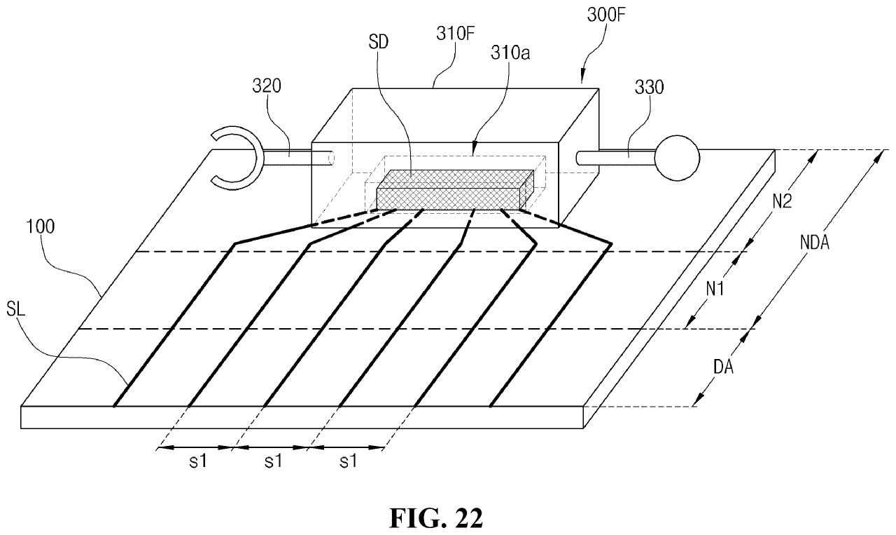

The control unit 300F of the stretchable display device according to yet another example embodiment of the present disclosure will be described with reference to FIG. 22.

FIG. 22 is a schematic view of a control unit of a stretchable display device according to yet another example embodiment of the present disclosure and shows the display panel together.

As shown in FIG. 22, the display panel 100 can include the display area DA and the non-display area NDA. The non-display area NDA can include a first non-display portion N1 and a second non-display portion N2, and the first non-display portion N1 can be disposed between the display area DA and the second non-display portion N2.

A plurality of signal lines SL can be provided in the display area DA of the display panel 100, and the source driving unit SD and the control unit 300F can be provided in the second non-display portion N2 of the non-display area NDA of the display panel 100. The source driving unit SD can be configured in the form of a driver IC chip.

The signal lines SL can extend into the first and second non-display portions N1 and N2 of the non-display area NDA and can be electrically connected to the source driving unit SD. The signal lines SL can be disposed with a predetermined space s1 therebetween in the display area DA and the first non-display portion N1, and the space between the signal lines SL can be narrowed in the second non-display portion N2.

In the second non-display portion N2 of the non-display area NDA, the control unit 300F can overlap the source driving unit SD. The control unit 300F can include the body portion 310F of a rectangular column shape, and the body portion 310F can overlap the source driving unit SD.

In this case, a body recess 310a can be provided at a bottom surface of the body portion 310F, and the source driving unit SD can be disposed in the body recess 310a.

The stretchable display device according to yet another example embodiment of the present disclosure can constantly maintain the space s1 between the signal lines SL constant up to the non-display area NDA, thereby increasing the stretchable area.

In addition, since the source driving unit SD is protected by the body portion 310F of the control unit 300F by overlapping the control unit 300, damage to the source driving unit SD due to stretching can be prevented or suppressed.

In the stretchable display device of the present disclosure, by providing the plurality of control units inside the frame surrounding the display panel and limiting the stretching range and the operating speed of the display panel, the display panel can be prevented or protected from being damaged due to excessive stretching.

Accordingly, the power consumption can be reduced due to the improved lifetime, thereby achieving the low power consumption.

In an example embodiment of the present application, a stretchable display device comprises: a display panel capable of being stretched in a first direction and a second direction; a frame coupled with an edge of the display panel; and a plurality of control units inside the frame, wherein a first control unit among the plurality of control units includes a body portion and a spheroidal joint, and the spheroidal joint includes a first joint portion and a second joint portion, and wherein one ends of the first joint portion and the second joint portion are coupled with the body portion, and other ends of the first joint portion and the second joint portion are coupled with respective spheroidal joints of other control units.

In an example embodiment of the present application, the first joint portion and the second joint portion include first coupling parts at the one ends and second coupling parts at the other ends, and wherein the first coupling parts are disposed inside the body portion, and the second coupling parts are disposed outside the body portion.

In an example embodiment of the present application, the first coupling parts of the first joint portion and the second joint portion move along a longitudinal direction of the body portion inside the body portion.

In an example embodiment of the present application, each of the first coupling parts of the first joint portion and the second joint portion includes at least one control hole.

In an example embodiment of the present application, the second coupling part of the first joint portion is coupled with a second coupling part of a second joint portion of another control unit, and the second coupling part of the second joint portion is coupled with a second coupling part of a first joint portion of one other control unit.

In an example embodiment of the present application, the plurality of control units further include a second control unit, and wherein the second control unit is vertically united with the first control unit and is disposed to correspond to a corner of the display panel.

In an example embodiment of the present application, the plurality of control units further include a third control unit united with the second control unit, wherein the first control unit is disposed in the first direction, and the second control unit and the third control unit are disposed in the second direction, and wherein the second control unit includes a body portion and first and second joint portions, and the third control unit includes a body portion and a single joint portion.

In an example embodiment of the present application, the third control unit is disposed to correspond to an area of the display panel where stretching is not necessary.

In an example embodiment of the present application, the plurality of control units further include a third control unit united with the first control unit, wherein the first control unit and the third control unit are disposed in the second direction, and the second control unit is disposed in the first direction, wherein the third control unit includes a body portion and first and second joint portions, and the first and second joint portions of the third control unit include first coupling parts and second coupling parts, and wherein number or area of control holes provided in the first coupling parts of the third control unit is smaller than number or area of control holes provided in the first coupling parts of the first control unit.

In an example embodiment of the present application, the first control unit is disposed to correspond to an area where a relatively fast operating speed for stretching is required, and the third control unit is disposed to correspond to an area where a relatively slow operating speed for stretching is required.

In an example embodiment of the present application, the plurality of control units further include a third control unit united with the first control unit, wherein the third control unit includes a body portion and first and second joint portions, and the first and second joint portions of the third control unit include first coupling parts and second coupling parts, and wherein an inside of the second coupling part of the first joint portion of the third control unit has an oval shape with a long axis and a short axis, and the second coupling part of the second joint portion of the third control unit has protrusions on both sides in the long axis.

In an example embodiment of the present application, the third control unit is disposed between adjacent first control units in the first direction.

In an example embodiment of the present application, the plurality of control units further include a third control unit united with the second control unit, wherein the third control unit includes a body portion and first and second joint portions, and wherein the body portion of the third control unit includes a body recess at a bottom surface thereof, and a source driving unit is disposed in the body recess.

In an example embodiment of the present application, the stretchable display device further comprises side portions respectively provided on both sides of the display panel and the frame in the first direction, wherein each of the side portions includes a first side unit and a second side unit that overlap each other in the second direction and move independently in the second direction.

In an example embodiment of the present application, the display panel includes: a plurality of rigid portions spaced apart from each other in the first direction and the second direction and provided with respective pixels; and a soft portion between adjacent rigid portions in the first direction or the second direction and provided with a stretchable line connecting the respective pixels.

It will be apparent to those skilled in the art that various modifications and variations can be made in the stretchable display device according to the above example embodiments of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device, comprising:
a display panel capable of being stretched in a first direction and a second direction;
a frame coupled with an edge of the display panel; and
a plurality of control units inside the frame,
wherein a first control unit among the plurality of control units includes a body portion and a spheroidal joint, and the spheroidal joint includes a first joint portion and a second joint portion, and
wherein one ends of the first joint portion and the second joint portion are coupled with the body portion, and other ends of the first joint portion and the second joint portion are coupled with respective spheroidal joints of other control units.

2. The stretchable display device of claim 1, wherein the first joint portion and the second joint portion include first coupling parts at the one ends and second coupling parts at the other ends, and
wherein the first coupling parts are disposed inside the body portion, and the second coupling parts are disposed outside the body portion.

3. The stretchable display device of claim 2, wherein the first coupling parts of the first joint portion and the second joint portion move along a longitudinal direction of the body portion inside the body portion.

4. The stretchable display device of claim 2, wherein each of the first coupling parts of the first joint portion and the second joint portion includes at least one control hole.

5. The stretchable display device of claim 2, wherein the second coupling part of the first joint portion is coupled with a second coupling part of a second joint portion of another control unit, and the second coupling part of the second joint portion is coupled with a second coupling part of a first joint portion of one other control unit.

6. The stretchable display device of claim 2, wherein the plurality of control units further include a second control unit, and
wherein the second control unit is vertically united with the first control unit and is disposed to correspond to a corner of the display panel.

7. The stretchable display device of claim 6, wherein the plurality of control units further include a third control unit united with the second control unit,
wherein the first control unit is disposed in the first direction, and the second control unit and the third control unit are disposed in the second direction, and
wherein the second control unit includes a body portion and first and second joint portions, and the third control unit includes a body portion and a single joint portion.

8. The stretchable display device of claim 7, wherein the third control unit is disposed to correspond to an area of the display panel where stretching is not necessary.

9. The stretchable display device of claim 6, wherein the plurality of control units further include a third control unit united with the first control unit,
wherein the first control unit and the third control unit are disposed in the second direction, and the second control unit is disposed in the first direction,
wherein the third control unit includes a body portion and first and second joint portions, and the first and second joint portions of the third control unit include first coupling parts and second coupling parts, and
wherein number or area of control holes provided in the first coupling parts of the third control unit is smaller than number or area of control holes provided in the first coupling parts of the first control unit.

10. The stretchable display device of claim 9, wherein the first control unit is disposed to correspond to an area where a relatively fast operating speed for stretching is required, and the third control unit is disposed to correspond to an area where a relatively slow operating speed for stretching is required.

11. The stretchable display device of claim 6, wherein the plurality of control units further include a third control unit united with the first control unit,
wherein the third control unit includes a body portion and first and second joint portions, and the first and second joint portions of the third control unit include first coupling parts and second coupling parts, and
wherein an inside of the second coupling part of the first joint portion of the third control unit has an oval shape with a long axis and a short axis, and the second coupling part of the second joint portion of the third control unit has protrusions on both sides in the long axis.

12. The stretchable display device of claim 11, wherein the third control unit is disposed between adjacent first control units in the first direction.

13. The stretchable display device of claim 6, wherein the plurality of control units further include a third control unit united with the second control unit,
wherein the third control unit includes a body portion and first and second joint portions, and
wherein the body portion of the third control unit includes a body recess at a bottom surface thereof, and a source driving unit is disposed in the body recess.

14. The stretchable display device of claim 1, further comprising side portions respectively provided on both sides of the display panel and the frame in the first direction,
wherein each of the side portions includes a first side unit and a second side unit that overlap each other in the second direction and move independently in the second direction.

15. The stretchable display device of claim 1, wherein the display panel includes:
a plurality of rigid portions spaced apart from each other in the first direction and the second direction and provided with respective pixels; and
a soft portion between adjacent rigid portions in the first direction or the second direction and provided with a stretchable line connecting the respective pixels.
